(19) United States
(12) Patent Application Publication
(10) Pub. No.: US 2004/0259325 A1
(43) Pub. Date: Dec. 23, 2004

(54) Wafer level chip scale hermetic package

(76) Inventor: Qing Gan, Fremont, CA (US)

Correspondence Address: Qing Gan, 41098 Bairo Ct., Fremont, CA, 94539, US

(21) Appl. No.: 10/870,609

(22) Filed: Jun. 17, 2004

Related U.S. Application Data
(60) Provisional application No. 60/479,362, filed on Jun. 19, 2003.

(51) Int. Cl. H01L 21/30

(52) U.S. Cl. 438/456

(57) ABSTRACT

A wafer level chip scale hermetic package is achieved by using filled via and hermetically sealed cavity between a cap wafer and a base wafer. The preparation of filled via is the first step of wafer processing, which is typically filled by copper plating. The filled via is used to connect a contact on the front side of a wafer to a contact on the backside of a wafer. The filled via can be either in the cap wafer and/or in the base wafer. The cavity is typically carved out from the cap wafer to house the device on the base wafer. The cap wafer is bonded to base wafer using bonding material. The bonding material can be one or more of many substances that exhibit acceptable adhesion, sealing and other properties to ensure a hermetical seal. The electrically conductive bonding material is preferred.

### CROSS REFERENCE TO RELATED APPLICATIONS

This application claims priority to U.S. Provisional Patent Application Ser. No. 60/479,362, filed on Jun. 19, 2003, entitled “Wafer level chip scale hermetic package with posts for interconnection,” which is incorporated herein by reference in its entirety.

### FIELD OF THE INVENTION

The present invention relates generally to a semiconductor packaging techniques, and mores specifically, towards to the design and fabrication of wafer level chip scale hermetic package (WLCSHP) for semiconductor devices including VLSI and MEMS.

### BACKGROUND OF THE INVENTION

Many semiconductor devices are sensitive to the contamination from atmosphere, dirt and moisture, as well as from mechanical and radiation loads until they are properly packaged. To protect them from harm, the devices have to be put in a hermetically sealed package. In the past, a device had to be cut or by other means separated from its wafer, and then it could be put into a hermetic package. In wafer-level packaging, packaging is performed while the device remains on the wafer. In this fashion, hundreds or thousands of packages can be created simultaneously, then tested and marked, and finally separated by sawing or other means.

Much research has been done for WLCSHP across the world, particularly for MEMS applications. But, very few have been applied to the commercial products due to various issues such as reliability and true hermetical sealing. In most WLCSHP processes reported so far, the capping wafer is aligned to the device wafer and bonded together. The capping wafer is usually a glass or silicon wafer. There are three key elements in the design and fabrication of wafer level package. The first is the cavities that house the devices, which protect the packaged devices from physical contact or damage during package process and device operation. The cavities can be fabricated on the capping wafer by either etching a recess cavity or built a spacer ring. The second is the bonding method. There are several bonding techniques including anodic bonding, glass frit bonding, silicon direct bonding and bonding using intermediate layers (such as solder, gold, eutectic, low temperature glass, or a polymer adhesive). Another key element is the design and fabrication of electrical feedthrough, which largely depends on the bonding process.

V. J. Adams, et al (U.S. Pat. No. 5,323,051) uses screen printing of frit glass compound to form a pattern of walls on the cap wafer, which surround the individual devices when align to the device wafer. After bonding by firing the glass, the walls provide a hermetic package around each unit. However, this process relies on a relatively thick patterned frit glass across the surface of a wafer, which is subject to non-uniformity in stand-off height, as well as to run out or bleed of the molten glass into active areas of the devices. To avoid potential bleed, large perimeters are required to leave enough spacing to the devices. Therefore, this package takes a lot of real estate and cannot achieve chip scale package.

Another package invented by Ruby et al (U.S. Pat. No. 6,376,280) used the similar package design. Instead, they use plated gold to form walls that surround devices when cold weld bonded to device wafers. There are no problems of run-out or bleed as that for glass, which allows the decrease of die size. However, the non-uniformity of wall height and surface roughness due to Au plating that may cause defects during the Au cold weld bonding and subsequently decrease yields and reliability.

To improve the uniformity of wall height and surface roughness, one method is to prepare cavities by etching of cap wafers. In John W. Orcutt's invention (U.S. Patent Publication No. 20020179986), the active devices are encapsulated by bonding with a cap wafer having cavities by etching of the silicon cap wafer. The cavities correspond to the location of the active circuits, and the unetched portions provide walls, which are topped by a thin film of sputtered glass or solder. The cap wafer is bonded to the device wafer by reflowing the glass film or solder to form a hermetic cavity around each active circuit. Precision of the etched cavities and walls, coupled with thin film glass or solder sealing of the wafers minimizes run-out or bleed of the glass or solder into active areas, thereby allowing the devices to be spaced in close proximity, supporting higher device density on the wafers.

In above-mentioned packages, holes through the cap wafer are used for test probes and bond wires or solder ball to the electrodes on device wafer. The tested devices are subsequently processed using conventional plastic molded package assembly techniques, including dicing, attaching the devices to a lead frame, wire bonding through the holes in the cap, and encapsulating with plastic molding compounds. The diameter of the holes has to be very large for the wire bonds to the electrodes, which limits the further reduction of die size. Wire bonding through contact holes can be quite challenge, expensive and time-consuming, thus it may decrease yields and increase cost.

Geefay, et al (U.S. Patent Application No. 20030119308) have developed a two-step etch process to form a small sloped via, allowing easy access to the inside walls of the via for metal sputtering or plating. A sloped via contact is used to connect a contact on active device wafer to a contact pad on the backside of the capping wafer. By placing contact pads on the back of the capping wafer, which can overlap the devices on the device wafer, thus the over-all surface area of the chip can be reduced. Furthermore, the contact pads on the back of a cap can be directly connected to external circuitry by solder bump or other technologies, subsequently eliminating the need for wire-bonding altogether. However, the second etch step, which creates sloped walls in the via, is performed on the capping wafer backside after wafer bonding and thinning of capping wafer. The wafer bonding used is gold cold weld bonding. Like holes through capping wafer, vias also provide lots of places that may fail hermetic seal before metal coating the via walls. Since only a thin metal coating (a few μm) on sloped via wall, the delamination from the wall and crack in the metal coating due to contamination, stress and other factors may not ensure a solid and reliable contact as well as hermetic seal.

All above mentioned hermetic packages are device specific, which are lack the capability to be an off-the-shelf solution. There is a need of wafer level chip scale hermetic package (WLCSHP) as a general solution for electronic devices. This package should be able to provide off-the-shelf like solution with high yield and reliability, cost effective and true hermetic seal for various devices.

### SUMMARY OF THE INVENTION

The present invention creates a wafer-level chip-scale package with via for interconnection, which can achieve hermetic seal. In this package, two wafers of the same size are involved. One wafer with a plurality of integrated circuits (IC) or microelectromechanical system (MEMS) devices is called device wafer, the other with a plurality of cavities and filled vias is called cap wafer. These two wafers are bonded together through a bonding layer to form a hermetically sealed cavity environment to protect the devices, i.e. a chip-scale hermetic package. This type chip-scale packages are formed simultaneously across the whole wafer for all devices to realize a wafer-level chip-scale package. Through the filled vias and/or posts, the devices can be electrically connected to contact pads on the back of the cap wafer.

The cap wafer is typically made of silicon, although materials such as glass, III-V compound semiconductors, ceramics or other materials can be used. Silicon is very strong, and semi-insulating silicon is ideal for packaging high frequency (such as radio frequency) devices, therefore silicon is an ideal cap wafer material. The vias can be with any shape and very small with equivalent diameter down to 5 microns. The vias can be fabricated by micro-machining, laser drilling, or other means. Metals such as Au, Cu or alloys then fill the vias by electro-chemical deposition. After polish to remove the extra metal on cap wafer, the wafer surface is very smooth. The cavities are then fabricated by micro-fabrication. Optionally, devices, such as inductor, capacitor, resistor and switch, can be fabricated inside the cavities of cap wafer, which are electronically connected to the IC or MEMS devices on the device wafer through the posts.

It should be appreciated that the present invention can be implemented in numerous ways, including as a process, an apparatus, a system, a device, a method, or a material. Further features and advantages of the present invention, as well as structure and operation of preferred embodiments of the present invention, are described in detail below in conjunction with the accompanying exemplary drawings. In the drawings, like reference numbers indicate identical or functionally similar elements.

### BRIEF DESCRIPTION OF THE DRAWINGS

FIG. 1 is a schematic diagram illustrating cross-sectional view of a preferred embodiment of the present invention.

FIG. 2 is a schematic diagram illustrating cross-sectional view of another preferred embodiment of the present invention.

FIG. 3 is a schematic diagram illustrating cross-sectional view of another preferred embodiment of the present invention.

FIG. 4 is a flowchart describing the process of fabricating wafer level chip scale hermetic package.

FIG. 5A-5G are cross-sectional views of the wafer section to show the fabrication steps of present invention. In this situation, vias and posts are used for electrical connections of both passive components on cap wafer to devices and package to outside.

### DETAILED DESCRIPTION

The following description is presented to enable any person skilled in the art to make and use the invention. Descriptions of specific embodiments and applications are provided only as examples and various modifications will be readily apparent to those skilled in the art. The general principles defined herein may be applied to other embodiments and applications without departing from the spirit and scope of the invention. Thus, the present invention is to be accorded the widest scope encompassing numerous alternatives, modifications and equivalents consistent with the principles and features disclosed herein. For purpose of clarity, details relating to technical material that is known in the technical fields related to the invention have not been described in detail so as not to unnecessarily obscure the present invention.

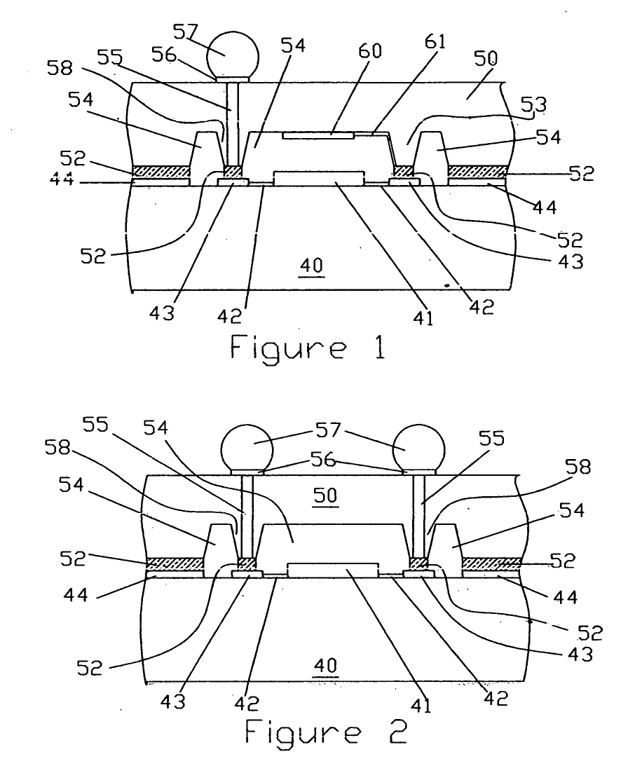

FIGS. 1-3 are schematic diagrams illustrating three preferred embodiments of a wafer level chip scale hermetic package (WLCSHP) for electronic and MEMS devices.

FIG. 1 shows a cross-sectional view of a preferred embodiment made in accordance with the teaching of the present invention. Typically, wafer 40 & 50 are silicon, but they also can be made of other materials such as glass, ceramics, other semiconductors, or other materials. On device wafer 40, device 41 is IC or MEMS device, which is electrically connected to pads 43 through interconnects 42. On cap wafer 50, a cavity 54 is etched out by either dry or wet etch process. The opening of the cavity can be any shape such as circular, rectangular, square, or oval as long as that will enclose device 41 and pad 43. There are a plurality of posts formed during cavity etch, which can be divided into two types. Post 58 has a via 55 in it for electrical connection to the outside of package and post 53 without via is for the electrical connection between device 60 to device 41. The top of the post can be any shape such as square, rectangle, circle or oval. The surface of post 53 are sloped to enable to fabricate interconnect 61. Via 55 is filled with electrical conductive material, which can be metal, alloy, polymer or any others. A preferred embodiment is electro-plated copper. The opening of via 55 also can be of any shape, such as square, rectangle, circle or oval, its narrowest side may be only 5-50 micrometers and depth may be 20-300 micrometers. Cap wafer 50 is bonded to device wafer 40 with bonding material 52. Bonding material 52 may be one or more of many substances that show good adhesion and hermetical seal, which is built on the cap wafer 50. Bonding material 52 should be electrical conductive, which can be metals, alloys, solder, polymer, glass or ceramics. The preferred embodiment is eutectic alloy or solder. The bond-mating surface 44 on wafer 40 is coated with the same bonding material as 52 or any material showing good adhesion, sealing and wetting to bonding material 52. The bonding can be performed in a controlled environment including vacuum or filled with other gases. A hermetically sealed environment 54 is formed between device wafer 40 and cap wafer 50 to protect devices 41 and 60. On the backside of cap wafer 50, a pad 56 is electrically connected to device pad 43 through via 55. Optionally, a solder bump 57 may be build on pad 56 for direct die attachment or using wire bond on pad 56 to other dies or printed circuit boards (PCB).

FIG. 2 is a cross-sectional view of an alternative of the present invention. In this embodiment, there is no passive component on the cap wafer 50. Therefore, there is only one type post, i.e. post 58 with via 55 on the cap wafer 50. The surface of post 58 can be either sloped or vertical.

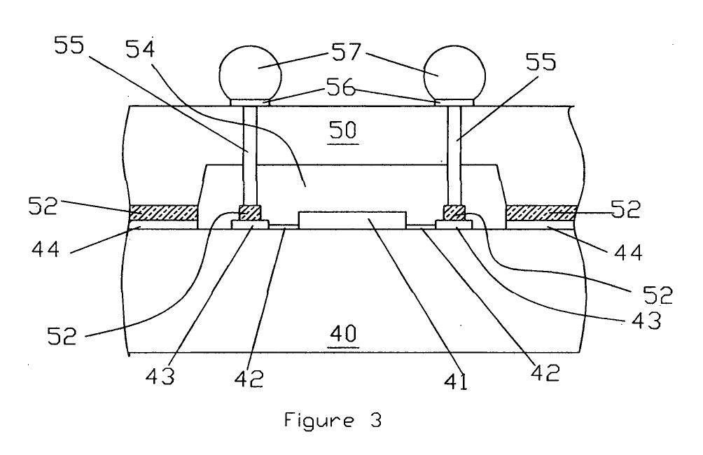

As shown in FIG. 3, even the wall that covers the filled via 55 in the cavity 54 may be completely removed to expose the lower part of via 55 as the post. This is possible by using metal with sufficient strength to fill via, such as copper, which may withstand possible high bonding force without collapsing or significant deformation.

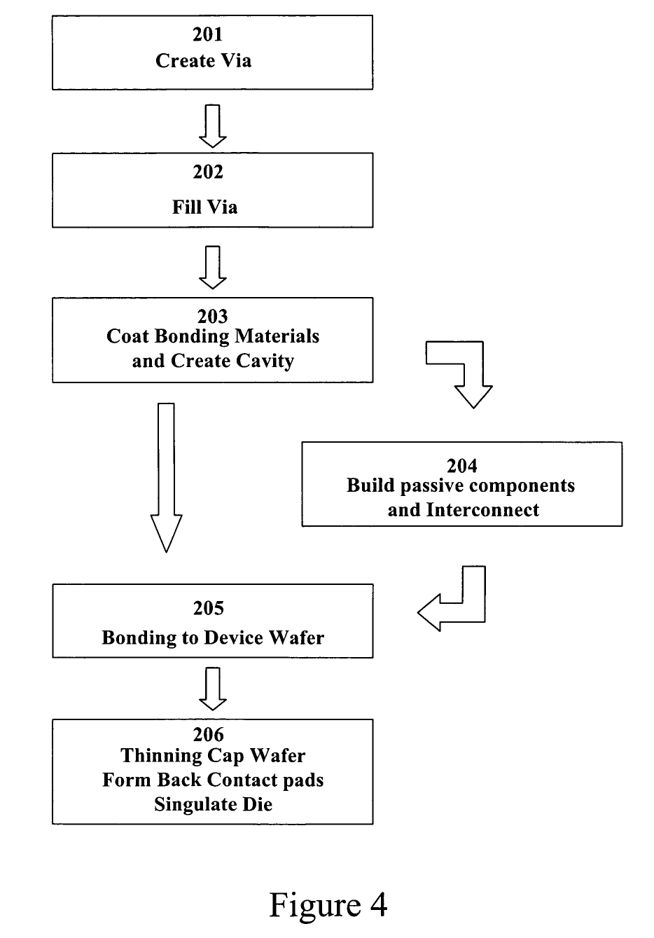

FIG. 4 is a flowchart describing the process of fabricating WLCSHP for the preferred embodiment in FIG. 1. In the first step, Step 201, a via is created in the cap wafer. This via is simply a hole in the wafer. The via is then filled with electrical conducting material in Step 202. In Step 203, bonding layer is coated on the cap wafer, which is patterned and cavity is created. As an option, passive components and interconnects are fabricated in the cavity (Step 204). In the following Step 205, device wafer is bonded to cap wafer in a controlled environment to form a hermetic seal. Finally in Step 206, the cap wafer is thinned from the backside to the desired thickness and expose the filled via, then the back contact pad is created. Solder bumps can be formed on the back contact pads if needed. Each die is finally separated from the wafer, which is ready for application.

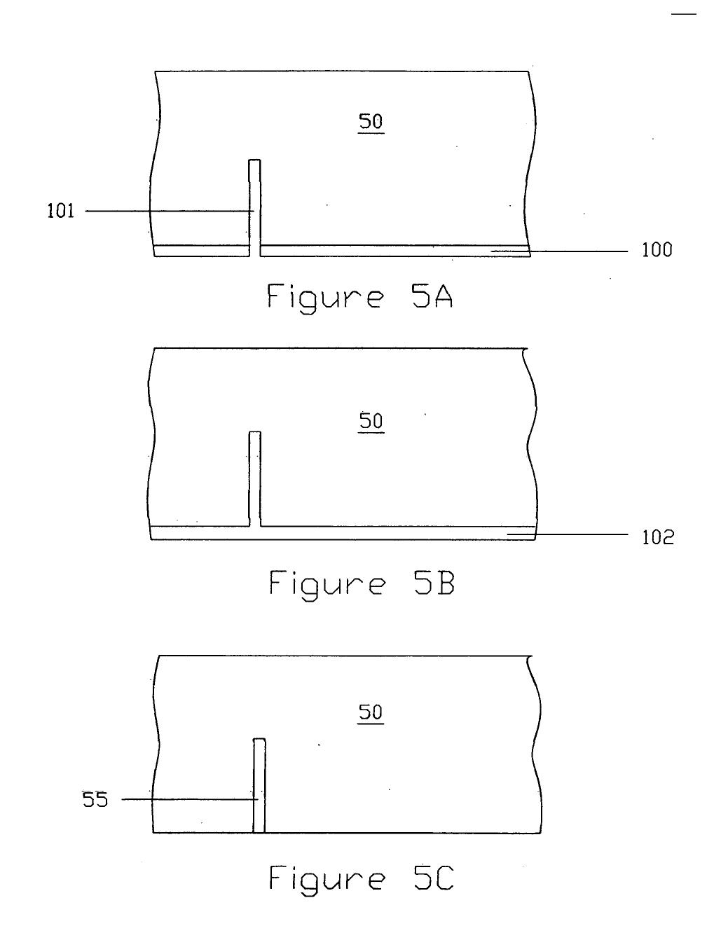

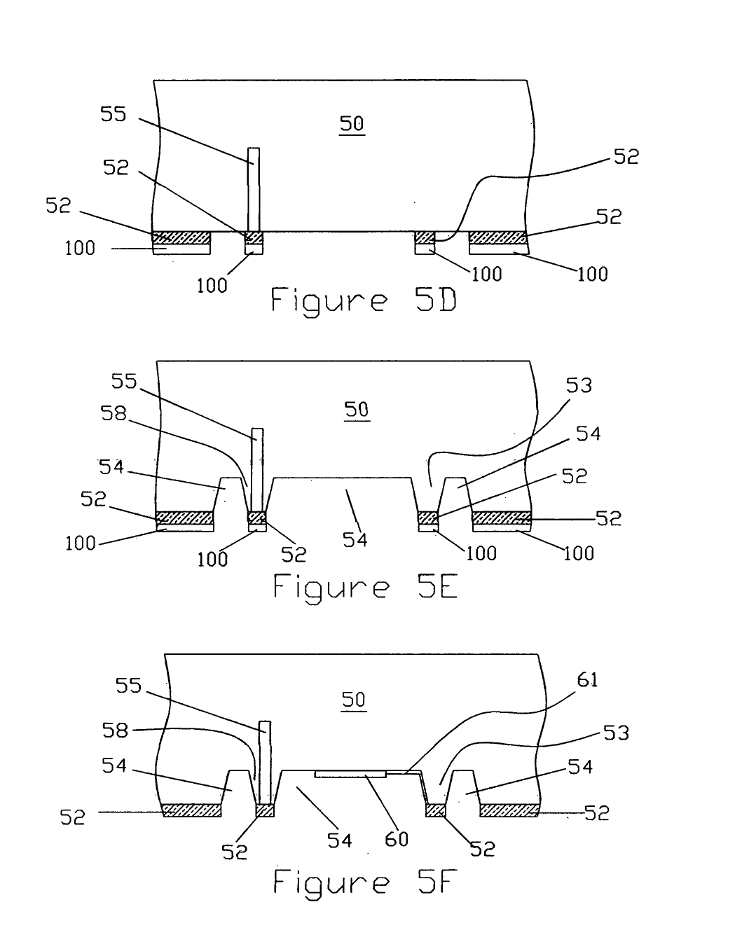

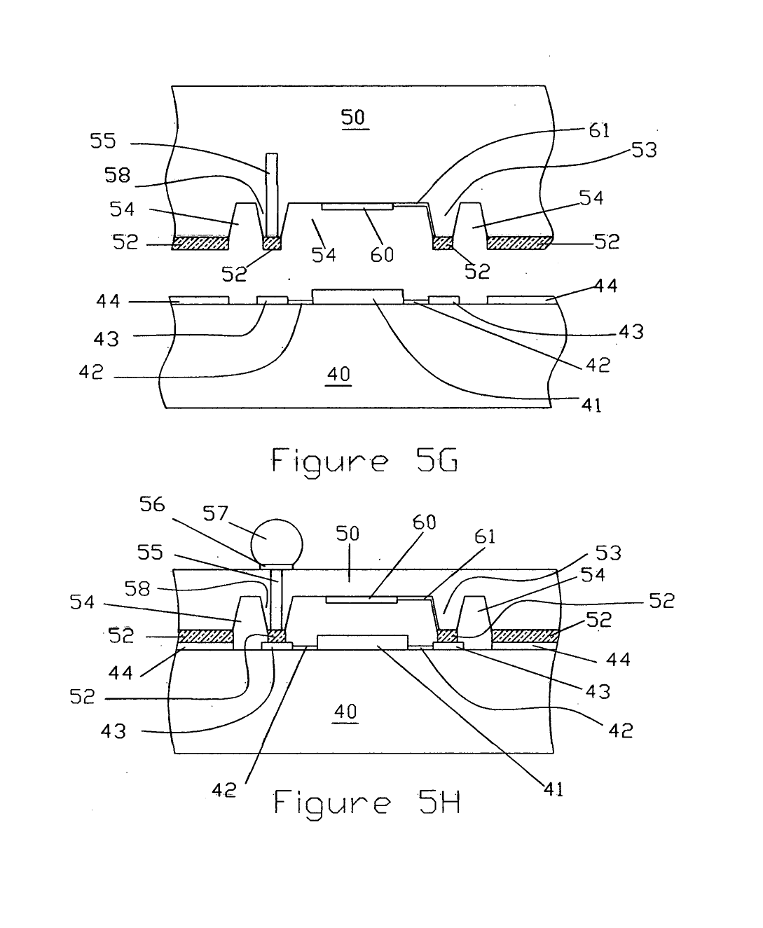

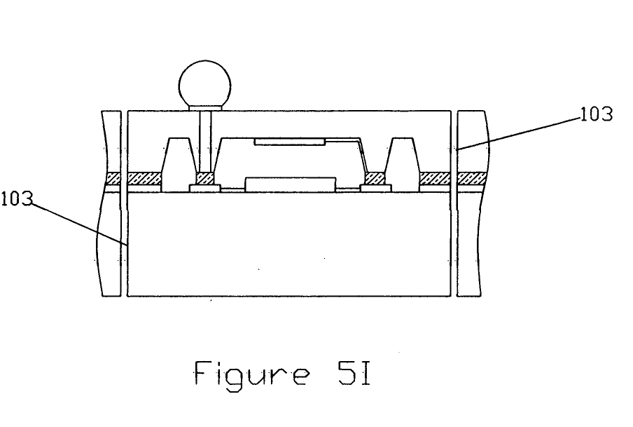

FIGS. 5A-5I are cross-sectional views of the wafer section to show the fabrication steps of present invention. In this embodiment, posts are used for electrical connections of both passive components on cap wafer to devices (post 53) and package to outside (post 58).

FIG. 5A shows cap wafer 50, which is made of silicon. Wafer 50 can also be other material such as glass, ceramics, or other semiconductors. The vias can be formed by various processes such as laser drill and etch. In the case of utilizing etch process, a layer of photoresist 100 is used. Photoresist 100 is coated, exposed and developed in a conventional photolithographic process to create an opening to define the opening of via 101. Then via 101 is formed by an etch process such as dry etch. One process is deep reactive ion etch (DRIE), which is capable to etch a very deep via with high aspect ratio. The surface can be vertical and smooth. The typical depth of via 101 is from 30 to 300 micrometer, while the narrowest side of the opening is from 5 to 30 micrometers. The photoresist is then removed by either wet or dry process.

FIG. 5B shows the wafer 50 after filling via 101 with an electrical conductive material 102. In the preferred embodiment, copper electro plating process is used. In this embodiment, a metal coating such as Ti/Pt/Cu is sputtered or otherwise deposited onto wafer 50. The best results are achieved by using the deposition process with excellent step coverage. This metal layer is used as seed layer for copper electro plating. Either the blank plating (plating the whole wafer surface) or selective plating (plating only the via 101 by masking the rest area using photolithography) can be used. Copper interconnection is the state of art of IC process technology. Copper electro-plating process for ULSI is readily available, however, which has to be modified or re-developed for the present invention due to the difference in via size.

FIG. 5C shows cap wafer 50 after chemo-mechanical polish (CMP) process to remove the extra electrical conductive material 102 on the wafer surface, thus formed a filled via 55. In the preferred embodiment of using copper, copper CMP process is readily available.

FIG. 5D shows cap wafer 50 after defining cavity-opening area. Electrical conductive bonding material 52 is coated or otherwise deposited on wafer surface by various methods such as spin coating, sputtering, vapor evaporation and plating, but not limited to these. The bonding material may be metal (e.g. gold, copper), alloy (e.g. AuSn eutectic, PbSn solders), electrical conductive ceramics and polymer (e.g. electrical conductive epoxy). The cavity opening and posts are then defined by patterning bonding material 52 using etch or lift-off process. In etch approach, photoresist 100 will be coated, exposed and developed by conventional photolithography processes to define cavity opening and posts. Then bonding material 52 will be selectively etched to expose surface area of wafer 50 for cavity etch. In the lift-off approach, bonding material 52 will be defined by lift-off process, and then a photoresist layer 100 will be coated and defined as shown in FIG. 5D used as a mask for cavity etch. In the preferred embodiment, the bonding material 52 will use eutectic alloys including AuSn eutectic, which will be patterned by lift-off process.

After etch wafer 50 using dry or wet process, the cavity 54, posts 53 and 58 may be formed as shown in FIG. 5E. As discussed in FIGS. 1-3, the surfaces of post 53 and post 58 may be sloped, vertical or even comprise via 55. The depth of the cavity can be from a few micrometers to over 100 micrometers depending on the applications.

In FIG. 5F, device 60 and interconnect 61 may be fabricated in the cavity 54. Interconnect 61 electrically connects to bonding material 52 on post 53. In this embodiment, the surface of post 53 is best to be slopped for the fabrication of reliable interconnect 61.

In FIG. 5G, cap wafer 50 and device wafer 40 are aligned to match bonding material 52 on wafer 50 to the bond-mating surface 43 (pads) and 44 on wafer 40. They are then bonded together under an applied bonding force. The bonding environment can be vacuum, inert gas, nitrogen or any acceptable environments. The bonding temperature can vary from room temperature up to a few hundred degrees depending on the property of bonding material 52. The bond-mating surface 43 and 44 on wafer 40 may be the same material as bonding materials 52 on wafer 50, or any electrical conductive materials that D have good adhesion or wetting property to bonding material 52. After bonding, a hermetically sealed cavity 54 is formed surrounding devices 41 and 60 to protect them. In a preferred embodiment, bonding material 52 is eutectic AuSn, and bond-mating surface 43 and 44 is gold. The bonding can be performed under a low bonding force at a temperature above AuSn eutectic temperature (e.g. 310° C.) or under a low bonding force at room temperature and then re-flow above the eutectic temperature.

In FIG. 5H, the cap wafer 50 may be thinned by conventional methods including grind, CMP, plasma etch, or wet etch to pre-defined thickness and to expose via 55. A bond pad 56 is then fabricated for next level interconnection. Either wire bond or solder bump may be used for connecting the WLCSHP devices to other devices. For example, a solder bump 57 is fabricated in FIG. 5H.

The wafer-level chip-scale packaged wafer may be electrically tested and the good dies may be marked, the dies are then singulated along street 103 as shown in FIG. 5I. Various singulation methods may be used including diamond sawing, scribe and break, laser sawing, or etch.

While the preferred embodiments of the present invention are described and illustrated herein, it will be appreciated that they are merely illustrative and that modifications can be made to these embodiments without departing from the spirit and scope of the invention. For instance, a filled via can be fabricated onto the device wafer itself. Also, multiple layers of caps can be stacked on top of one another. Thus, the invention is intended to be defined only in terms of the following claims.

What is claimed is:

1. A method for manufacturing a wafer-level chip-scale hermetic package, comprising:
providing a first wafer and a second wafer;
removing a portion from the first wafer to form a via;
filling the via with electrical conducting material;
removing a portion from the first wafer to form a cavity;
removing a portion from the first wafer to form a post;
forming a pad on the second wafer, the pad substantially matching the post;
interposing bonding material between the post and the pad;
interposing bonding material between surface surrounding cavity and mating surface on the second wafer; and
bonding the first wafer and second wafer with the bonding material to create a hermetically sealed environment between the first and second wafers.
providing a contact on the backside of the wafer, electrically connected to the front contact through the filled via.

2. The method of claim 1, wherein the first wafer consists of silicon.

3. The method of claim 2, wherein the via is no more than 50 um wide.

4. The method of claim 3, wherein the via is no more than 30 um wide.

5. The method of claim 3, wherein forming a via includes using a deep reactive ion etching (DRIE) process.

6. The method of claim 3, wherein forming a via includes using a laser drilling process.

7. The method of claim 3, wherein filling the via with electrical conductive material.

8. The method of claim 7, wherein the conductive material selected from the group consisting Ti, Pt, NiCr, Ni, Ta, TaN, Au and Cu.

9. The method of claim 7, wherein filling the via includes plating.

10. The method of claim 2, wherein forming a cavity and a post includes using reactive ion etching (RIE) process.

11. The method of claim 10, wherein interposing bonding material includes depositing bonding material on the post and surface surrounding cavity.

12. The method of claim 11, wherein the bonding material includes conductive bonding material.

13. The method of claim 12, wherein the conductive bonding material is a metal selected from the group consisting of gold-tin, gold, and tin-based alloys.

14. A wafer-level chip-scale hermetic package, comprising:
a first wafer and a second wafer;
a cavity formed from the first wafer;
a post formed from the first wafer;
a contact on the backside of the wafer
a contact on the front side of the wafer;
a via through the wafer connecting the front contact to the back contact,
wherein the via is filled with metal.
bonding material joining the first wafer and the second wafer.

15. The wafer-level chip-scale hermetic package of claim 14, wherein the first wafer consists of silicon.

16. The wafer-level chip-scale hermetic package of claim 14, wherein the via is no more than 50 um wide.

17. The wafer-level chip-scale hermetic package of claim 16, wherein the via is no more than 30 um wide.

18. The wafer-level chip-scale hermetic package of claim 16, wherein filling the via with electrical conductive material.

19. The wafer-level chip-scale hermetic package of claim 18, wherein the conductive material is selected for the group consisting Ti, Pt, NiCr, Ta, TaN, Au and Cu.

20. The wafer-level chip-scale hermetic package of claim 14, wherein the bonding material includes conductive bonding material.

21. The wafer-level chip-scale hermetic package of claim 20, wherein the conductive bonding material is a metal selected from the group consisting of gold-tin, gold and tin-based alloys.
